(19) United States
(12) Patent Application Publication
(10) Pub. No.: US 2026/0338873 A1
(43) Pub. Date: Oct. 29, 2026

(54) STATE DIAGNOSTIC APPARATUS FOR BATTERY AND STATE DIAGNOSTIC METHOD THEREOF

(71) Applicants: HYUNDAI MOTOR COMPANY, SEOUL (KR); KIA CORPORATION, SEOUL (KR)

(72) Inventors: Hyun Jun Jo, Hwaseong-si (KR); Si Joong Kim, Hwaseong-si (KR); Hyun Jun Jang, Hwaseong-si (KR); Tae Kyu Kang, Hwaseong-si (KR)

(73) Assignees: HYUNDAI MOTOR COMPANY, SEOUL (KR); KIA CORPORATION, SEOUL (KR)

(21) Appl. No.: 19/568,143

(22) Filed: Mar. 16, 2026

(30) Foreign Application Priority Data
Apr. 29, 2025 (KR) 10-2025-0056540

(51) Int. Cl. G01R 31/392; G01R 31/36; G01R 31/367; G01R 31/3835

(52) U.S. Cl. CPC G01R 31/392; G01R 31/3646; G01R 31/367; G01R 31/3835

(57) ABSTRACT

A state diagnostic apparatus for a battery includes a transceiver module that receives battery data of at least one battery cell, and a processor that calculates a differential capacity based on the received battery data, determines an abnormal type for an abnormal state of the at least one battery cell based on the calculated differential capacity, identifies an outlier based on the determined abnormal type, and determines a diagnostic type corresponding to the abnormal state based on the identified outlier.

### CROSS REFERENCE TO RELATED APPLICATIONS

This application claims the benefit of priority to Korean Patent Application No. 10-2025-0056540, filed in the Korean Intellectual Property Office on Apr. 29, 2025, the entire contents of which are incorporated herein by reference.

### TECHNICAL FIELD

The present disclosure relates to a state diagnostic apparatus for a battery and a state diagnostic method thereof, and more particularly, relates to technologies for diagnosing an abnormal state of the battery and determining the type of the abnormal state.

### BACKGROUND

A battery system refers to the clustering of two or more batteries in a state in which the two or more batteries are connected in series or in parallel with each other. In other words, in the battery system, hundreds of battery cells or thousands of battery cells are connected in series or in parallel with each other. For example, the occurrence of deterioration in one of the hundreds of battery cells or the thousands of battery cells has an influence on adjacent battery cells due to heat transfer. In other words, if an abnormality occurs in even one cell, thermal runaway may occur in the entire battery system. Particularly, a micro short circuit (MSC), an internal short circuit (ISC), or a similar issue may occur in a battery cell due to lithium plating or a similar phenomenon. This may directly lead to thermal runaway and fire of the battery system.

Furthermore, a decisive defective factor that causes a failure of a battery is generally known as an internal short circuit. However, an abnormal state of the battery is caused by a dependent and interactive influence between battery cells, and a clear mechanism for this abnormal state is not defined. For example, if ion diffusion at the electrode-electrolyte interface of the battery cell is inhibited, a probability of lithium plating may increase and a short circuit may occur in the battery cell. In other words, there are various factors except for the short circuit in the abnormal state of the battery. There is a need for a technology capable of diagnosing the abnormal state of the battery.

To address the above-mentioned problem, there are many studies for diagnosing an abnormal state of a battery cell. For example, a technology for monitoring a sensing value of a sensor provided in the battery cell or diagnosing a state of a battery cell based on changes in the sensing value in a battery management system (BMS) provided in an electric vehicle has been developed.

However, a battery diagnostic technology capable of considering the mass production conditions of a battery loaded into an electric vehicle and applied to a dynamic driving environment has been barely developed. For example, an existing battery state diagnostic technology uses a passive diagnostic scheme for monitoring a sensing value, which may only diagnose whether battery cell is short-circuited. In other words, the existing battery state diagnostic technology has a limitation in diagnosing an abnormal state of the battery cell. Thus, the necessity of an active diagnostic technology for analyzing an electrochemical state of a battery based on an environmental condition applicable to the electric vehicle is emerging. Particularly, there is a need for a technology capable of determining whether there is an abnormal state of a specific battery cell in the battery system in a time series and determining the type and the degree of the abnormal state.

### SUMMARY

The present disclosure has been made to solve the above-mentioned problems occurring in the prior art, while the advantages achieved by the prior art are maintained intact.

An aspect of the present disclosure provides a state diagnostic apparatus for a battery for determining a type of an abnormal state based on data of a battery cell and a state diagnostic method thereof.

Another aspect of the present disclosure provides a state diagnostic apparatus for a battery for quantifying an abnormal state of a battery and analyzing the abnormal state and a state diagnostic method thereof.

The technical problems to be solved by the present disclosure are not limited to the problems mentioned above, and any other technical problems not mentioned herein will be clearly understood from the following description by those skilled in the art to which the present disclosure pertains.

According to an aspect of the present disclosure, a state diagnostic apparatus for a battery may include a transceiver module that receives battery data of at least one battery cell and a processor that calculates a differential capacity based on the received battery data, determines an abnormal type for an abnormal state of the at least one battery cell based on the calculated differential capacity, calculates an outlier based on the determined abnormal type, and determines a diagnostic type corresponding to the abnormal state based on the calculated outlier.

In an embodiment, the processor may calculate a curve for the differential capacity as a function of a voltage, based on the battery data and may calculate an outline of at least one of a peak or a valley based on the calculated curve.

In an embodiment, the processor may set a plurality of voltage values based on the curve. The plurality of voltage values may include a first voltage value and a second voltage value.

In an embodiment, the processor may calculate a first relative value for the differential capacity corresponding to the first voltage value and may calculate a second relative value for the differential capacity corresponding to the second voltage value.

In an embodiment, the processor may determine whether the first relative value is within a first reference range, may determine whether the second relative value is within a second reference range, and may determine the abnormal type depending on the determined result.

In an embodiment, the processor may calculate the outlier based on a weight corresponding to the outline of at least one of the peak or the valley and the abnormal type.

In an embodiment, the processor may determine whether the outlier is greater than or equal to a threshold and may determine the diagnostic type corresponding to the outlier depending on the determined result.

In an embodiment, the processor may determine the diagnostic type as a short-term diagnosis if the outlier is greater than or equal to the threshold.

In an embodiment, the processor may calculate an accumulated outlier by accumulating outliers during a certain duration, and may determine the diagnostic type as a long-term diagnosis if the accumulated outlier is greater than or equal to a threshold accumulated value.

In an embodiment, the processor may preset the abnormal type and the diagnostic type based on a characteristic of the battery cell.

According to another aspect of the present disclosure, a state diagnostic method of a state diagnostic apparatus a battery may include receiving battery data of at least one battery cell, calculating a differential capacity based on the received battery data, determining an abnormal type for an abnormal state of the at least one battery cell based on the calculated differential capacity, calculating an outlier based on the determined abnormal type, and determining a diagnostic type corresponding to the abnormal state based on the calculated outlier.

In another embodiment, the calculation of the differential capacity may include calculating a curve for the differential capacity according to a voltage, based on the battery data, and calculating an outline of at least one of a peak or a valley based on the calculated curve.

In another embodiment, the calculating of the differential capacity may further include setting a plurality of voltage values based on the curve. The plurality of voltage values may include a first voltage value and a second voltage value.

In another embodiment, the calculation of the differential capacity may further include calculating a first relative value for the differential capacity corresponding to the first voltage value and calculating a second relative value for the differential capacity corresponding to the second voltage value.

In another embodiment, determining the abnormal type may include determining whether the first relative value is within a first reference range, determining whether the second relative value is within a second reference range, and determining the abnormal type depending on the determined result.

In another embodiment, the calculation of the outlier may include calculating the outlier based on a weight corresponding to the outline of at least one of the peak or the valley and the abnormal type.
a. In another embodiment, determining the diagnostic type may include determining whether the outlier is greater than or equal to a threshold and determining the diagnostic type corresponding to the outlier depending on the determined result.

In another embodiment, determining the diagnostic type may further include determining the diagnostic type as a short-term diagnosis if the outlier is greater than or equal to the threshold.

In another embodiment, determining the diagnostic type may further include calculating an accumulated outlier by accumulating outliers during a certain duration, and determining the diagnostic type as a long-term diagnosis if the outlier is greater than or equal to a threshold accumulated value.

In another embodiment, the state diagnostic method may further include presetting the abnormal type and the diagnostic type based on a characteristic of the battery cell.

### BRIEF DESCRIPTION OF THE FIGURES

The above and other objects, features, and advantages of the present disclosure will be more apparent from the following detailed description taken in conjunction with the accompanying drawings:

FIG. 1 is a drawing for describing a battery system including a state diagnostic apparatus for a battery according to an embodiment of the present disclosure;

FIG. 2 is a block diagram illustrating a state diagnostic apparatus for a battery according to an embodiment of the present disclosure;

FIG. 3A is an example of battery data according to the related art;

FIG. 3B is an example of battery data according to an embodiment of the present disclosure;

FIGS. 4A and 4B are examples of an abnormal type according to an embodiment of the present disclosure;

FIG. 5 is an example of a diagnostic type according to an embodiment of the present disclosure;

FIG. 6 is a flowchart for describing a state diagnostic method of a state diagnostic apparatus for a battery according to an embodiment of the present disclosure;

FIGS. 7, 8, and 9 are flowcharts for describing in detail a state diagnostic method of a state diagnostic apparatus for a battery according to an embodiment of the present disclosure; and

FIG. 10 is a block diagram illustrating a computing system according to an embodiment of the present disclosure.

### DETAILED DESCRIPTION

Hereinafter, some embodiments of the present disclosure will be described in detail with reference to the exemplary drawings. In adding the reference numerals to the components of each drawing, it should be noted that the identical component is designated by the identical numerals even when they are displayed on other drawings. Further, in describing the embodiment of the present disclosure, a detailed description of well-known features or functions will be ruled out in order not to unnecessarily obscure the gist of the present disclosure.

In describing the components of the embodiment of the present disclosure, terms such as first, second, “A”, “B”, (a), (b), and the like may be used. These terms are only used to distinguish one component from another component, but do not limit the corresponding components, irrespective of the order or priority of the corresponding components. Furthermore, unless otherwise defined, all terms, including technical and scientific terms, used herein have the same meaning as being generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

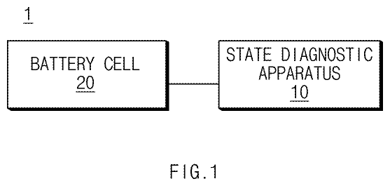

Hereinafter, embodiments of the present disclosure will be described in detail with reference to FIGS. 1 to 10.

FIG. 1 is a drawing for describing a battery system 1 including a state diagnostic apparatus 10 for a battery according to an embodiment of the present disclosure.

Referring to FIG. 1, the battery system 1 may include the state diagnostic apparatus 10 and at least one battery cell 20. Herein, the battery system 1 may include a battery management system (BMS) and a battery pack. The state diagnostic apparatus 10 may be provided in the BMS or the battery pack. For example, at least some of the respective components of the state diagnostic apparatus 10 may be implemented by supplementing or adding a function of a configuration included in an existing BMS.

In an embodiment, the state diagnostic apparatus 10 may receive battery data from the battery cell 20. Herein, the battery data may include temperature, current, voltage, state of charge (SOC), or the like of the battery cell 20.

The state diagnostic apparatus 10 may determine the abnormal type and the diagnostic type for the abnormal state of the battery cell 20 based on the received battery data. Herein, the abnormal state may refer to a state in which performance is degraded by various factors, such as process failure, short circuit, deterioration, an increase in resistance, swelling, lithium plating, and electrode unevenness. The abnormal type may refer to a type classified by a factor corresponding to an abnormal state. Herein, the abnormal state may include process failure, short circuit, deterioration, an increase in resistance, swelling, lithium plating, electrode unevenness, or the like. Furthermore, the diagnostic type may refer to a type corresponding to a response method for processing the abnormal state. For example, if the abnormal state occurs, there may be a change in battery data. The state diagnostic apparatus 10 may calculate a differential capacity based on the changed battery data and may determine an abnormal type based on the differential capacity. Herein, the differential capacity may refer to the rate of change in capacity dQ, for a voltage change rate, dV, during the charging and discharging processes of the battery. In other words, the differential capacity may indicate dQ/dV.

In an embodiment, the battery cell 20 may refer to one independent battery cell that includes a negative terminal and a positive terminal and is capable of being physically divided. Thus, a battery module in which at least one battery cell 20 is provided by being connected in series and/or in parallel with each other may be configured.

If the battery cell 20 is in an abnormal state, a change in differential capacity may occur. The differential capacity may be influenced by a condition, such as temperature, current, voltage, or a state of charge (SOC) of the battery cell 20, and various factors, including process failure, a short circuit, deterioration, an increase in resistance, swelling, lithium plating, electrode unevenness, and the like. Thus, the abnormal state of the battery cell 20 may be determined by a curve indicating differential capacity as a function of voltage. An existing battery state diagnostic technology may determine whether the battery 20 is in an abnormal state using differential capacity; however, it has a limitation in that it is difficult to identify the type of abnormality based on the abnormal state. In other words, the existing battery state diagnostic technology may diagnose the battery cell 20, which is in a defective state, but it has a problem identifying the cause of the defective state.

To address the above problem, the present disclosure proposes a state diagnostic apparatus 10 capable of determining the type of an abnormal state based on battery data and quantifying the abnormal state of the battery to analyze the abnormal state.

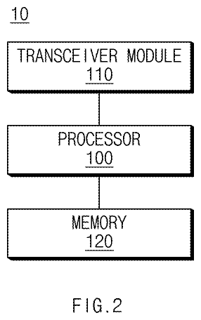

FIG. 2 is a block diagram illustrating a state diagnostic apparatus 10 for a battery according to an embodiment of the present disclosure.

Referring to FIG. 2, the state diagnostic apparatus 10 may include a processor 100, a transceiver module 110, and a memory 120.

In an embodiment, the transceiver module 110 may receive battery data of a battery cell, which is measured while the battery is charged and/or discharged. Herein, the battery data may include temperature, current, voltage, state of charge (SOC), or similar information. Furthermore, the battery data may also provide a voltage profile for both voltage and capacity.

The transceiver module 110 may transmit a diagnostic type corresponding to a battery cell, as determined by the processor 100, to an output module (not shown). Thus, a user of the battery may receive an abnormal type and a diagnostic type for the battery cell.

The transceiver module 110 may be connected to at least one battery cell to communicate with at least one battery cell.

In an embodiment, the processor 100 may calculate a voltage profile for a voltage and a capacity based on the received battery data. Thereafter, the processor 100 may calculate a differential capacity based on the calculated voltage profile. In other words, the processor 100 may differentiate a capacity Q of the battery cell into a voltage V of the battery cell to calculate a differential capacity (dQ/dV) of the battery cell. Thus, the processor 100 may calculate a curve for the differential capacity (dQ/dV) as a function of voltage V, that is, a V−dQ/dV curve. Thereafter, the processor 100 may calculate an outline of at least one of a peak or a valley based on the calculated V−dQ/dV curve. Herein, the peak and valley outlines may include a movement direction, a width change, a height change, or the like for the peak of the curve and the valley of the curve. For example, the peak and the valley may vary in position and shape depending on the abnormal type. Thus, the processor 100 may estimate an abnormal type based on the peak and valley outline. For example, the peak of a battery cell with large resistance may move to the right over time, while the peak of a battery cell with small resistance may move to the left over time. For another example, the peak outline may be influenced by the homogeneity and heterogeneity of an electrode of the battery cell. A battery cell in which lithium-ion diffusion in the electrode is not performed smoothly may have a degraded distinctiveness of the peak. In other words, the processor 100 may estimate and determine an abnormal type for an abnormal state of the battery cell based on the peak outline indicating a change in peak.

The processor 100 may set a plurality of voltage values based on the V−dQ/dV curve. For example, the plurality of voltage values may include a first voltage value and a second voltage value. Alternatively, for another example, the plurality of voltage values may include first, second, and third voltage values. Herein, the processor 100 may set the plurality of voltage values around the peak and the valley. For example, the first voltage value may be a value smaller than the voltage value at which a peak occurs, and the second voltage value may be a value greater than the voltage value at which a peak occurs. As described above, the processor 100 may set the plurality of voltage values to two, three, or more than three. Thus, the processor 100 may set a plurality of relative values to two, three, or more than three.

The processor 100 may calculate relative values for differential capacities respectively corresponding to the plurality of voltage values. For example, the processor 100 may calculate a first relative value for the differential capacity corresponding to the first voltage value in the V−dQ/dV curve. Simultaneously, the processor 100 may calculate a second relative value for the differential capacity corresponding to the second voltage value in the V−dQ/dV curve. For example, the processor 100 may obtain battery data measured while each battery cell is charged and/or discharged a certain number of times via the transceiver module 110. Herein, it is assumed that a certain number of times is n. Thus, the processor 100 may calculate n V−dQ/dV curves based on n pieces of battery data. In other words, the processor 100 may calculate n differential capacities corresponding to each of the first voltage value and the second voltage value. The first relative value may refer to a relative value calculated based on the average and standard deviation of the n differential capacities corresponding to the first voltage value. Meanwhile, the second relative value may refer to a relative value calculated based on the average and standard deviation of the n differential capacities corresponding to the second voltage value. Alternatively, the processor 100 may calculate the slopes of the differential capacities corresponding to each of the first voltage value and the second voltage value in the n V−dQ/dV curves. The first relative value may refer to a relative value for each of n slopes corresponding to the first voltage value. Meanwhile, the second relative value may refer to a relative value for each of n slopes corresponding to the second voltage value. Thus, the processor 100 may combine the first relative value, the second relative value, the calculated curve, and the like to calculate the peak outline in detail over time during a certain number of times.

The processor 100 may determine whether the first relative value is within a first reference range and may determine whether the second relative value is within a second reference range. For example, the first reference range may be −N1 to N1, and the second reference range may be −N2 to N2. Herein, each of N1 and N2 may be any numerical value based on the characteristics of the battery. In other words, the processor 100 may preset an abnormal type and a diagnostic type corresponding to N1 and N2 based on the characteristics of the battery cell. For example, the processor 100 may preset the abnormal type and the diagnostic type using a table generated based on empirical data, according to the characteristics of the battery cell. Thus, the processor 100 may determine the abnormal type and the diagnostic type optimized for the characteristics of the battery cell based on empirical data, such as experimental results.

As an example, if the first relative value X is greater than −N1 and is less than N1 (−N1<X<N1) and the second relative value Y is greater than −N2 and is less than N2 (−N2<Y<N2), the peak outline may be set to “0” and the abnormal type may be set to “a”. If the first relative value X is greater than or equal to N1 (N1≤X) and the second relative value Y is greater than or equal to N2 (N2≤Y), the peak outline may be set to “1” and the abnormal type may be set to “b”. If the first relative value X is greater than N1 (N1≤X) and the second relative value Y is greater than −N2 and is less than N2 (−N2<Y<N2), the peak outline may be set to “2” and the abnormal type may be set to “c”. If the first relative value X is greater than or equal to N1 (N1≤X) and the second relative value Y is less than or equal to −N2 (Y≤−N2), the peak outline may be set to “3” and the abnormal type may be set to “d”. If the first relative value X is greater than −N1 and is less than N1 (−N1<X<N1) and the second relative value Y is less than or equal to −N2 (Y≤−N2), the peak outline may be set to “4” and the abnormal type may be set to “e”. If the first relative value X is less than or equal to −N1 (X≤−N1) and the second relative value Y is less than or equal to −N2 (Y≤−N2), the peak outline may be set to “5” and the abnormal type may be set to “f”. If the first relative value X is less than or equal to −N1 (X≤−N1) and the second relative value Y is greater than −N2 and is less than N2 (−N2<Y<N2), the peak outline may be set to “6” and the abnormal type may be set to “g”. If the first relative value X is less than or equal to −N1 (X≤−N1) and the second relative value Y is greater than or equal to N2 (N2≤Y), the peak outline may be set to “7” and the abnormal type may be set to “h”. If the first relative value X is greater than −N1 and is less than N1 (−N1<X<N1) and the second relative value Y is greater than or equal to N2 (N2≤Y), the peak outline may be set to “8” and the abnormal type may be set to “i”.

As described above, the processor 100 may set, but is not limited to, the 9 abnormal types and the 9 peak outlines. If the plurality of voltage values includes the first to third voltage values, the processor 100 may set more abnormal types and more peak outlines. Thereafter, the processor 100 may determine a peak outline based on the reference range of each of the first relative value and the second relative value, and may simultaneously determine an abnormal type of an abnormal state.

The processor 100 may calculate an outlier based on a weight corresponding to the peak outline and the abnormal type. Herein, the weight may vary with the peak outline and the abnormal type. The weight may be preset based on empirical data according to the characteristics of the battery cell. For example, if the peak outline is 1 and the abnormal type is b, the outlier may be a value obtained by adding a value (wx1*|X|) obtained by multiplying an absolute value of the first relative value X by a weight wx1 and a value (wy1*|Y|) obtained by multiplying an absolute value of the second relative value Y by a weight wy1. In other words, the outlier for the peak outline of 1 and the abnormal type of b may be wx1*|X|+wy1*|Y|. For example, if the peak outline is 2 and the abnormal type is c, the outlier may be a value obtained by adding a value (wx2*|X|) obtained by multiplying the absolute value of the first relative value X by a weight wx2 and a value (wy2*|Y|) obtained by multiplying the absolute value of the second relative value Y by a weight wy2. In other words, the outlier for the peak outline of 2 and the abnormal type of c may be wx2*|X|+wy2*|Y|.

The processor 100 may determine whether the outlier is greater than or equal to a threshold. Herein, the threshold may be preset in response to the abnormal type. For example, if there are 9 abnormal types, the threshold may be set for each of the 9 abnormal types. The processor 100 may determine a diagnostic type corresponding to the outlier depending on the determined result. Herein, the diagnostic type may refer to a response method in which a user (or a customer) of the battery processes the abnormal state of the battery cell. Thus, the processor 100 may provide the user with the determined diagnostic type via the transceiver module 110 and may guide the user to perform after-service (A/S) and precision diagnosis of the battery cell with the abnormal state.

As an example, if the outlier is greater than or equal to the threshold, the processor 100 may determine the diagnostic type as a short-term diagnosis. Herein, the short-term diagnosis may refer to an immediate diagnosis. If the outlier calculated during one charging and discharging is greater than or equal to the threshold, the processor 100 may determine the diagnostic type of battery cell as the short-term diagnosis. For example, if the capacity of a battery cell provided in an electric vehicle deteriorates, is degraded, or reduced, the mileage of the electric vehicle may be reduced. However, it may be determined whether the above-mentioned abnormal state is not an abnormal type that poses a threat to the safety of the driver of the electric vehicle. In this case, if the outlier is greater than or equal to the threshold, the processor 100 may determine the diagnostic type of the battery cell as the short-term diagnosis and may guide the user to replace the battery cell with the abnormal state. For another example, an abnormal state that poses a threat to the safety of the driver, such as a short circuit caused by lithium plating, may occur in the battery cell. If the outlier for the abnormal type for the abnormal state is greater than or equal to the threshold, the processor 100 may control the output of a notification via a diagnostic trouble code. Thus, the processor 100 may provide the driver with an aggressive warning and aggressive monitoring. Furthermore, the processor 100 may execute a physical control operation, such as changing the color of a warning light on the dashboard to red, or triggering a mechanical disconnection of a main relay to cut off high-voltage power. In another example, the processor 100 may initiate a control operation to physically engage a locking mechanism of a charging port to prevent further charging, thereby providing an aggressive warning and proactive safety intervention.

As an example, the processor 100 may calculate an accumulated outlier, where outliers from a certain duration are accumulated. Thereafter, if the accumulated outlier is greater than or equal to a threshold accumulated value, the processor 100 may determine the diagnostic type as a long-term diagnosis. Herein, the certain duration may refer to a duration when charging and discharging are repeated n times, and the long-term diagnosis may refer to a gradual diagnosis. In other words, if the accumulated outlier in which the outlier is accumulated while charging and discharging are performed n times is greater than or equal to the threshold accumulated value, the processor 100 may determine the diagnostic type of the battery cell as the long-term diagnosis. Alternatively, if an average outlier of the outliers accumulated while charging and discharging are repeated n times is greater than or equal to the threshold, the processor 100 may determine the diagnostic type of the battery cell as the long-term diagnosis. For example, if the capacity of the battery cell provided in the electric vehicle deteriorates, is degraded, or reduced, and the above-mentioned abnormal state is accumulated, a new abnormal state may occur. If the accumulated outlier for the abnormal type of the above-mentioned abnormal state is greater than or equal to the threshold accumulated value, the processor 100 may diagnose whether there is a new abnormal state to gradually monitor whether there is the new abnormal state. When the diagnostic type is determined as the long-term diagnosis, the processor 100 initiates specific and tangible control operations beyond merely displaying a result. Specifically, the processor 100 may modify the inverter control logic to forcibly limit the maximum output power (derating) of the battery or perform a mechanical control to increase the operating speed of a water pump or a cooling fan in the thermal management system. Additionally, the processor 100 may activate a dedicated service indicator light or physically trigger a hardware switch within the battery management system (BMS) to establish a redundant safety circuit. Thus, the processor 100 may provide gradual monitoring and preventive measures to mitigate the development of new abnormal states.

As described above, if the outlier is greater than or equal to the threshold, the processor 100 may determine that the battery cell is in an abnormal state and may determine an abnormal type and a diagnostic type corresponding to the abnormal state. Thus, before the battery becomes inoperable, the processor 100 may identify and diagnose an abnormal state of the battery cell early. Furthermore, the processor 100 may classify an abnormal type and may set a threshold in the calculated outlier to be able to perform a precise diagnosis, thus preventing misdiagnosis. For example, it is assumed that an abnormal state, such as a short circuit, occurs in the battery cell. Herein, as a leak current occurs by a current flowing in an electrical/electronic component provided outside the battery cell, except for the short circuit in the battery cell, a short circuit may occur. In other words, the short circuit may occur due to an external factor, as well as an internal factor of the battery cell. Thus, the processor 100 may classify an abnormal type for the short circuit due to an external factor and may set a threshold corresponding to that abnormal type of short circuit. In other words, the state diagnostic apparatus 10 according to the present disclosure may quantify the abnormal state to classify the abnormal type, thus robustening misdiagnosis.

The processor 100 provided in the state diagnostic apparatus 10 for the battery according to an embodiment of the present disclosure may selectively include a processor known to those skilled in the art to execute various pieces of control logic performed in the present disclosure, an application-specific integrated circuit (ASIC), another chipset, a logic circuit, a register, a communication modem, a data processing device, or the like. Furthermore, if control logic is implemented with software, the processor 100 may be implemented with a set of program modules. Herein, the program module may be stored in the memory 120 and may be executed by the processor 100.

In an embodiment, the memory 120 may store a table for a predetermined abnormal type and diagnostic type based on the characteristics of the battery cell.

The memory 120 may store a program, data, and the like necessary for the processor 100 to diagnose a state of the battery. In other words, the memory 120 may store data or a program necessary for each component of the state diagnostic apparatus 10 to perform an operation and function, data generated during the process of performing the operation and function, or the like.

The memory 120 may be inside or outside the processor 100 and may be connected to the processor 100. If the memory 120 is the well-known information storage means that is known to be able to record, erase, update, and read out data, there is no special limit on the type thereof. For example, the information storage means may include a random access memory (RAM), a flash memory, a read-only memory (ROM), an electrically erasable programmable ROM (EEPROM), a register, or the like. Furthermore, the memory 120 may store program codes in which processes executable by the processor 100 are defined.

As described above, the state diagnostic apparatus 10 for the battery according to the present disclosure may determine the type of abnormal state in the battery and may quantify the abnormal state, thereby improving the accuracy and reliability of diagnosing the state of the battery. Furthermore, the state diagnostic apparatus 10 may easily determine the type of the abnormal state of the battery, thus providing a response method according to the type.

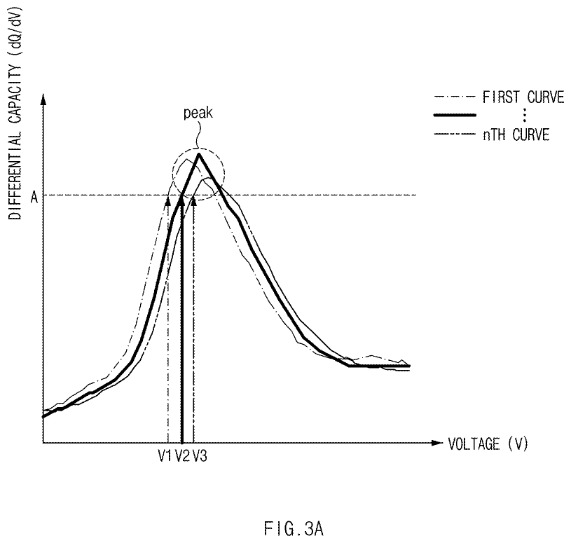

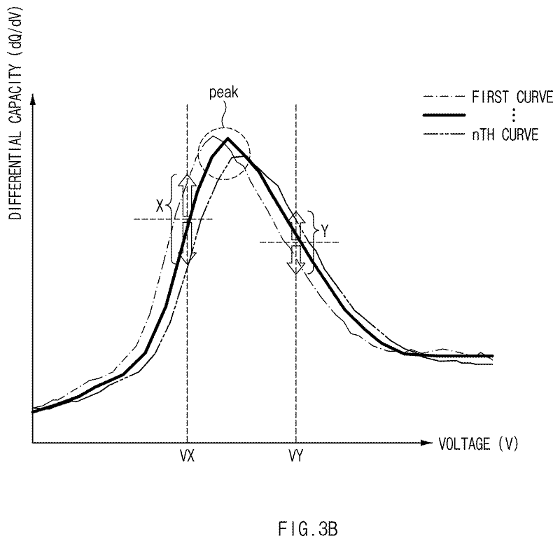

FIG. 3A is an example of battery data according to the related art. FIG. 3B is an example of battery data according to an embodiment of the present disclosure.

Referring to FIG. 3A, an existing battery state diagnostic technology may determine whether a battery 20 is in an abnormal state using a differential capacity. Herein, it is assumed that the number of battery cells provided in a battery is N. For example, the existing battery state diagnostic technology may calculate a maximum value and a minimum value for the differential capacity to calculate a peak outline. As shown in FIG. 3A, first to third voltages V1 to V3 may be set, and a differential capacity for each voltage may be calculated and stored. Herein, first voltage V1<second voltage V2<third voltage. As such, first to Mth voltages may be set and a differential capacity for each voltage may be calculated and stored. Thereafter, the existing battery state diagnostic technology may extract a maximum value and a minimum value from the stored differential capacity and may calculate a peak outline. Thus, the existing battery state diagnostic technology may calculate M×N differential capacities to calculate a peak outline. In other words, because the existing battery state diagnostic technology needs many memories and a large amount of computation to calculate the M×N differential capacities, it is difficult to apply the existing battery state diagnostic technology to a system in an electric vehicle.

Referring to FIG. 3B, a processor 100 may differentiate the capacity Q of a battery cell into the voltage V of the battery cell to calculate the differential capacity (dQ/dV) of the battery cell. Thus, the processor 100 may calculate a curve for the differential capacity (dQ/dV) as a function of voltage V, that is, a V−dQ/dV curve. Thereafter, the processor 100 may calculate a peak outline based on the calculated V−dQ/dV curve. The processor 100 may set a plurality of voltage values based on the V−dQ/dV curve. As shown in FIG. 3B, the plurality of voltage values may include a first voltage value, VX, and a second voltage value, VY. Herein, it is assumed that the number of battery cells provided in a battery is N. Thus, the processor 100 may calculate 2×N differential capacities to calculate a peak outline. For another example, the plurality of voltage values may include first to third voltage values. Thus, the processor 100 may calculate 3×N differential capacities to calculate a peak outline. In other words, the processor 100, according to the present disclosure, may consume smaller amounts of memory and computation than the existing battery state diagnostic technology, thus making it easily applicable to a system in an electric vehicle.

The processor 100 may calculate relative values for differential capacities respectively corresponding to the plurality of voltage values. For example, the processor 100 may calculate a first relative value for the differential capacity corresponding to the first voltage value in the V−dQ/dV curve. Simultaneously, the processor 100 may calculate a second relative value for the differential capacity corresponding to the second voltage value in the V−dQ/dV curve. Thus, the processor 100 may combine the first relative value, the second relative value, the calculated curve, and the like to calculate the peak outline in detail over time during a certain number of times.

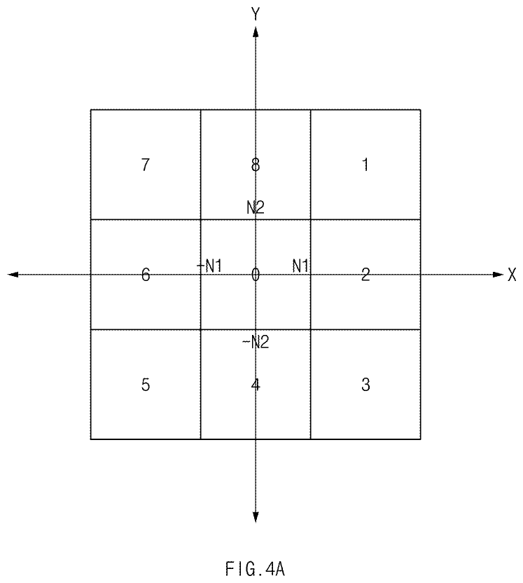

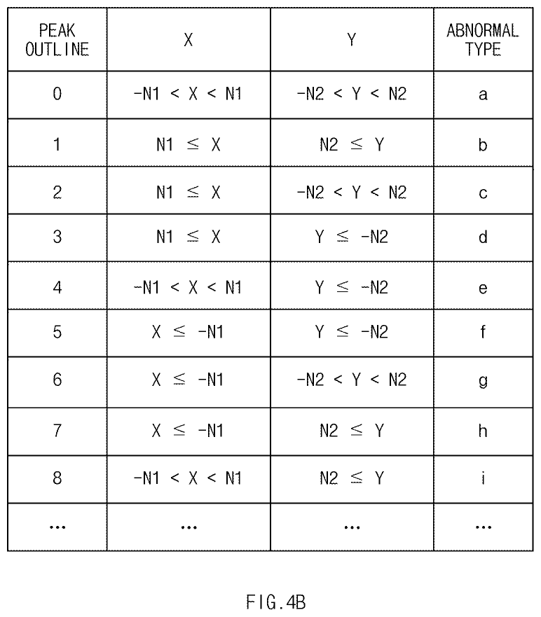

FIGS. 4A and 4B are examples of an abnormal type according to an embodiment of the present disclosure.

Referring to FIGS. 4A and 4B, a processor 100 may determine whether a first relative value is within a first reference range and may determine whether a second relative value is within a second reference range. For example, the first reference range may be −N1 to N1, and the second reference range may be −N2 to N2. Herein, each of N1 and N2 may be any numerical value based on the characteristics of the battery. In other words, the processor 100 may preset an abnormal type and a diagnostic type corresponding to N1 and N2 based on the characteristics of the battery cell. For example, the processor 100 may preset the abnormal type and the diagnostic type using a table generated based on empirical data, according to the characteristics of the battery cell. Thus, the processor 100 may determine the abnormal type and the diagnostic type optimized for the characteristic of the battery cell based on empirical data, such as experimental results.

As shown in FIGS. 4A and 4B, if the first relative value X is greater than −N1 and is less than N1 (−N1<X<N1) and the second relative value Y is greater than −N2 and is less than N2 (−N2<Y<N2), the peak outline may be set to “0” and the abnormal type may be set to “a”.

If the first relative value X is greater than or equal to N1 (N1≤X) and the second relative value Y is greater than or equal to N2 (N2≤Y), the peak outline may be set to “1” and the abnormal type may be set to “b”. For example, if the peak outline is 1, the peak may increase in width and height over time.

If the first relative value X is greater than or equal to N1 (N1≤X) and the second relative value Y is greater than −N2 and is less than N2 (−N2<Y<N2), the peak outline may be set to “2” and the abnormal type may be set to “c”.

If the first relative value X is greater than or equal to N1 (N1≤X) and the second relative value Y is less than or equal to −N2 (Y≤−N2), the peak outline may be set to “3” and the abnormal type may be set to “d”. For example, if the peak outline is 3, the peak of the V−dQ/dV curve may move to the left over time.

If the first relative value X is greater than −N1 and is less than N1 (−N1<X<N1) and the second relative value Y is less than or equal to −N2 (Y≤−N2), the peak outline may be set to “4” and the abnormal type may be set to “e”.

If the first relative value X is less than or equal to −N1 (X≤−N1) and the second relative value Y is less than or equal to −N2 (Y≤−N2), the peak outline may be set to “5” and the abnormal type may be set to “f”. For example, if the peak outline is 5, the peak may decrease in width and height over time.

If the first relative value X is less than or equal to −N1 (X≤−N1) and the second relative value Y is greater than −N2 and is less than N2 (−N2<Y<N2), the peak outline may be set to “6” and the abnormal type may be set to “g”. For example, if the peak outline is 6, a left V−dQ/dV may decrease around the peak over time, and the peak may move to the right while a right V−dQ/dV curve is maintained.

If the first relative value X is less than or equal to −N1 (X≤−N1) and the second relative value Y is greater than or equal to N2 (N2≤Y), the peak outline may be set to “7” and the abnormal type may be set to “h”. For example, if the peak outline is 7, the peak of the V−dQ/dV curve may not be crushed to move to the right over time.

If the first relative value X is greater than −N1 and is less than N1 (−N1<X<N1) and the second relative value Y is greater than or equal to N2 (N2≤Y), the peak outline may be set to “8” and the abnormal type may be set to “i”. For example, if the peak outline is 8, the right V−dQ/dV may change around the peak over time and the peak may move to the right while the left V−dQ/dV curve remains unchanged.

As described above, the processor 100 may set, but is not limited to, the 9 abnormal types and the 9 peak outlines. If the plurality of voltage values includes first to third voltage values, the processor 100 may set more abnormal types and more peak outlines. Thereafter, the processor 100 may determine a peak outline based on the reference range of each of the first relative value and the second relative value and may simultaneously determine an abnormal type of an abnormal state. Herein, the abnormal state may include process failure, short circuit, deterioration, an increase in resistance, swelling, lithium plating, electrode unevenness, or the like.

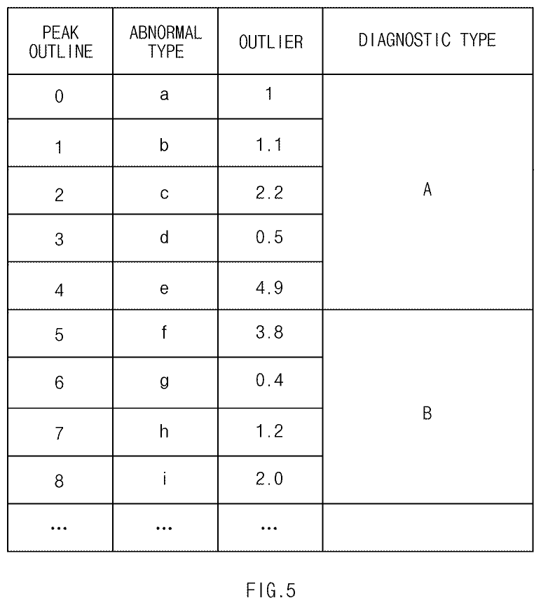

FIG. 5 is an example for a diagnostic type according to an embodiment of the present disclosure.

Referring to FIG. 5, a processor 100 may calculate an outlier based on a weight corresponding to a peak outline and an abnormal type. Herein, the weight may vary with the peak outline and the abnormal type. The weight may be preset based on empirical data according to the characteristics of the battery cell. For example, if the peak outline is 1 and the abnormal type is b, the outlier may be a value obtained by adding a value (wx1*|X|) obtained by multiplying an absolute value of a first relative value X by a weight wx1 and a value (wy1*|Y|) obtained by multiplying an absolute value of a second relative value Y by a weight wy1. In other words, the outlier for the peak outline of 1 and the abnormal type of b may be wx1*|X|+wy1*|Y|. For example, if the peak outline is 2 and the abnormal type is c, the outlier may be a value obtained by adding a value (wx2*|X|) obtained by multiplying the absolute value of the first relative value X by a weight wx2 and a value (wy2*|Y|) obtained by multiplying the absolute value of the second relative value Y by a weight wy2. In other words, the outlier for the peak outline of 2 and the abnormal type of c may be wx2*|X|+wy2*|Y|.

The processor 100 may determine whether the outlier is greater than or equal to a threshold. Herein, the threshold may be preset in response to the abnormal type. For example, if there are 9 abnormal types (a to i), the threshold may be set for each of the 9 abnormal types. The processor 100 may determine a diagnostic type A or B corresponding to the outlier, depending on the determined result. Herein, the diagnostic type may refer to a response method in which a user (or a customer) of the battery processes the abnormal state of the battery cell. Thus, the processor 100 may provide the user with the determined diagnostic type via a transceiver module 110 and may guide the user to perform after-service (A/S) and precision diagnosis of the battery cell with the abnormal state.

For example, if the outlier is greater than or equal to the threshold, the processor 100 may determine the diagnostic type as short-term diagnosis A. In this case, short-term diagnosis A may refer to an immediate diagnosis. If the outlier calculated during one charging and discharging is greater than or equal to the threshold, the processor 100 may determine the diagnostic type of battery cell as the short-term diagnosis. For example, if the capacity of a battery cell provided in an electric vehicle deteriorates, is degraded, or reduced, the mileage of the electric vehicle may be reduced. However, it may be determined whether the above-mentioned abnormal state is not an abnormal type that poses a threat to the safety of the driver of the electric vehicle. In this case, if the outlier is greater than or equal to the threshold, the processor 100 may determine the diagnostic type of the battery cell as the short-term diagnosis A and may guide the user to replace the battery cell with the abnormal state. For another example, an abnormal state that poses a threat to the safety of the driver, such as a short circuit by lithium plating, may occur in the battery cell. If the outlier for the abnormal type for the abnormal state is greater than or equal to the threshold, the processor 100 may control to output a notification via a diagnostic trouble code. Thus, the processor 100 may provide the driver with an aggressive warning and aggressive monitoring.

For example, the processor 100 may calculate an accumulated outlier where outliers from a certain duration are accumulated. Thereafter, if the accumulated outlier is greater than or equal to a threshold accumulated value, the processor 100 may determine the diagnostic type as the long-term diagnosis B. Herein, a certain duration may refer to a duration when charging and discharging are repeated n times, and the long-term diagnosis B may refer to a gradual diagnosis. In other words, if an accumulated outlier in which the outlier is accumulated while charging and discharging are repeated n times is greater than or equal to the threshold accumulated value, the processor 100 may determine the diagnostic type of the battery cell as the long-term diagnosis B. Alternatively, if an average outlier of the outliers accumulated while charging and discharging are repeated n times is greater than or equal to the threshold, the processor 100 may determine the diagnostic type of the battery cell as the long-term diagnosis B. For example, if the capacity of the battery cell provided in the electric vehicle deteriorates, is degraded, or reduced, and the above-mentioned abnormal state is accumulated, a new abnormal state may occur. If the accumulated outlier for the abnormal type of the above-mentioned abnormal state is greater than or equal to the threshold accumulated value, the processor 100 may diagnose whether there is a new abnormal state, and gradually monitor whether there is a new abnormal state.

As described above, if the outlier is greater than or equal to the threshold, the processor 100 may determine that the battery cell is in an abnormal state and may identify an abnormal type and a diagnostic type corresponding to the abnormal state. Thus, before the battery becomes inoperable, the processor 100 may identify and diagnose an abnormal state of the battery cell early. Furthermore, the processor 100 may classify an abnormal type and may set a threshold in the calculated outlier to perform a precise diagnosis, thus preventing misdiagnosis. For example, it is assumed that an abnormal state, such as a short circuit, occurs in the battery cell. Herein, as a leak current occurs when a current flows in an electrical/electronic component provided outside the battery cell, except for a short circuit within the battery cell, a short circuit may occur. In other words, the short circuit may occur due to an external factor, as well as an internal factor of the battery cell. Thus, the processor 100 may classify an abnormal type of short circuit due to an external factor and may set a threshold corresponding to that abnormal type of short circuit. In other words, a state diagnostic apparatus 10 according to the present disclosure may quantify the abnormal state to classify the abnormal type, thereby robustifying against misdiagnosis.

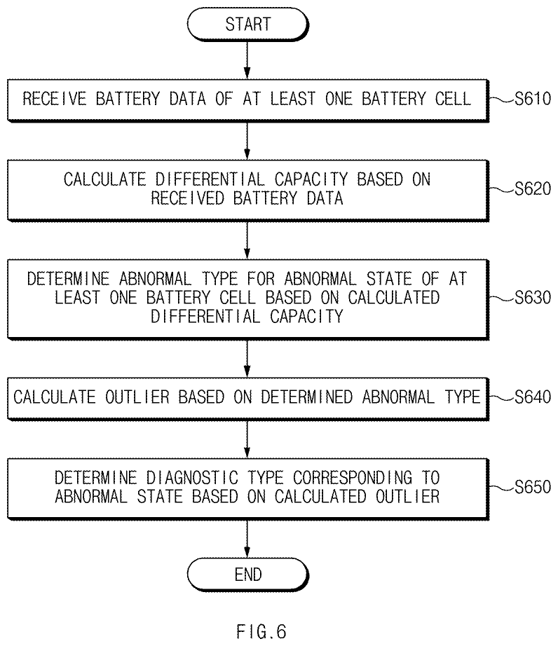

FIG. 6 is a flowchart illustrating a state diagnostic method of a state diagnostic apparatus 10 for a battery, according to an embodiment of the present disclosure.

Referring to FIG. 6, in S610, battery data of at least one battery cell may be received. For example, a transceiver module 110 of FIG. 2 may receive battery data from the battery cell, which is measured while the battery is being charged and/or discharged. In S620, a differential capacity may be calculated based on the received battery data. For example, a processor 100 of FIG. 2 may calculate a voltage profile for a voltage and a capacity based on the received battery data. Thereafter, the processor 100 may calculate a differential capacity based on the calculated voltage profile.

In S630, an abnormal type for an abnormal state of at least one battery cell may be determined based on the calculated differential capacity. For example, the processor 100 may calculate a curve for the differential capacity as a function of voltage, that is, a V−dQ/dV curve. Thereafter, the processor 100 may calculate an outline of at least one of a peak or a valley based on the calculated V−dQ/dV curve. The processor 100 may estimate and determine an abnormal type for an abnormal state of the battery cell based on the peak outline indicating a change in the peak.

In S640, an outlier may be calculated based on the determined abnormal type. For example, the processor 100 may calculate an outlier based on a weight corresponding to the peak outline and the abnormal type.

In S650, a diagnostic type corresponding to the abnormal state may be determined based on the calculated outlier. For example, if the outlier is greater than or equal to a threshold, the processor 100 may determine the diagnostic type as a short-term diagnosis.

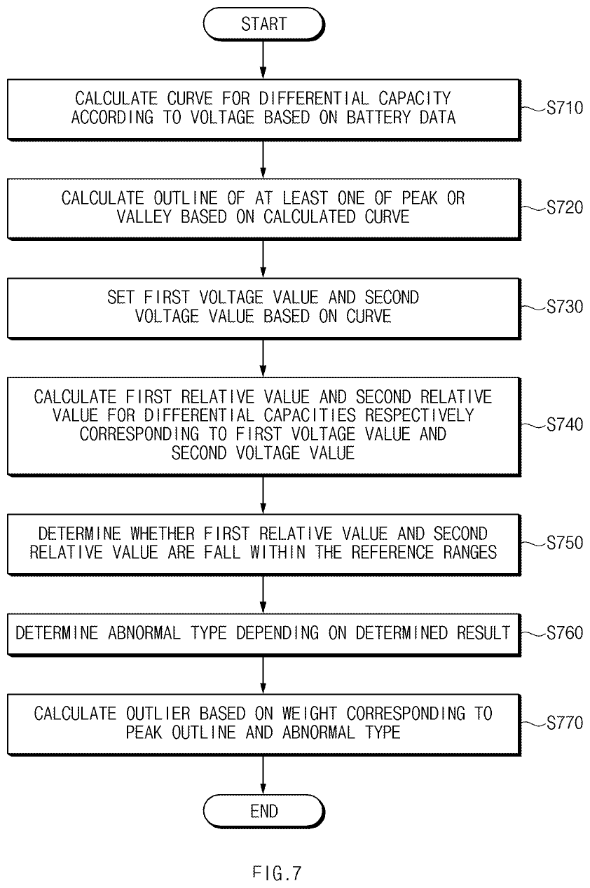

FIGS. 7 to 9 are flowcharts that describe in detail a state diagnostic method of a state diagnostic apparatus 10 for a battery, according to an embodiment of the present disclosure.

Referring to FIG. 7, in S710, a curve for differential capacity according to voltage may be calculated based on battery data. For example, a processor 100 may calculate a voltage profile for a voltage and a capacity based on the received battery data. Thereafter, the processor 100 may calculate a differential capacity based on the calculated voltage profile. Thus, the processor 100 may calculate a curve for the differential capacity as a function of voltage, that is, a V−dQ/dV curve.

In S720, an outline of at least one of a peak or a valley may be calculated based on the calculated curve. For example, the processor 100 may calculate a peak outline based on the calculated V−dQ/dV curve.

In S730, a first voltage value and a second voltage value may be set based on the curve. For example, the processor 100 may set a plurality of voltage values based on the V−dQ/dV curve. The plurality of voltage values may include the first voltage value and the second voltage value.

In S740, a first relative value and a second relative value for differential capacities respectively corresponding to the first voltage value and the second voltage value, may be calculated. For example, the processor 100 may calculate relative values for differential capacities respectively corresponding to the plurality of voltage values. The processor 100 may calculate the first relative value for the differential capacity corresponding to the first voltage value in the V−dQ/dV curve. Simultaneously, the processor 100 may calculate the second relative value for the differential capacity corresponding to the second voltage value in the V−dQ/dV curve.

In S750, it may be determined whether the first relative value and the second relative value fall within the reference ranges. For example, the processor 100 may determine whether the first relative value is within a first reference range and may determine whether the second relative value is within a second reference range. Herein, the first reference range may be −N1 to N1, and the second reference range may be −N2 to N2.

In S760, an abnormal type may be determined according to the determined result. For example, the processor 100 may determine a peak outline based on the reference range of each of the first relative value and the second relative value, and may simultaneously determine an abnormal type of an abnormal state.

In S770, an outlier may be calculated based on a weight corresponding to the peak outline and the abnormal type. Herein, the weight may vary with the peak outline and the abnormal type. The weight may be preset based on empirical data according to the characteristics of the battery cell.

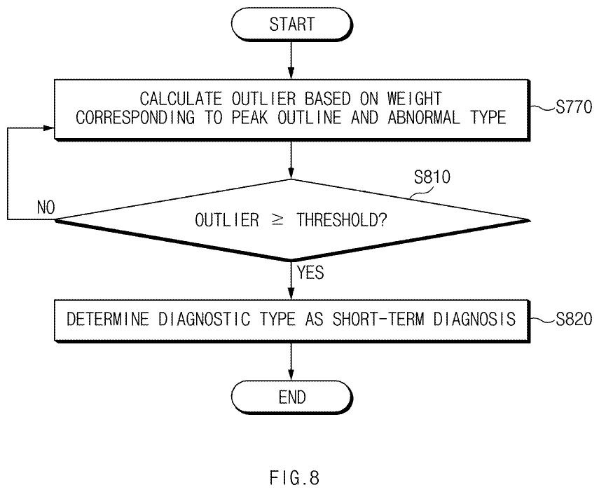

Referring to FIG. 8, in S810, it may be determined whether the outlier is greater than or equal to a threshold. For example, the processor 100 may determine whether the outlier is greater than or equal to the threshold. Herein, the threshold may be preset in response to the abnormal type.

If it is determined that the outlier is greater than or equal to the threshold, in S820, a diagnostic type may be determined as a short-term diagnosis. Herein, the short-term diagnosis may refer to an immediate diagnosis. If the outlier calculated during one charging and discharging is greater than or equal to the threshold, the processor 100 may determine the diagnostic type of the battery cell as the short-term diagnosis.

On the other hand, if it is determined that the outlier is less than the threshold, the processor 100 may return to S770 and may determine a diagnostic type except for the short-term diagnosis based on the outlier.

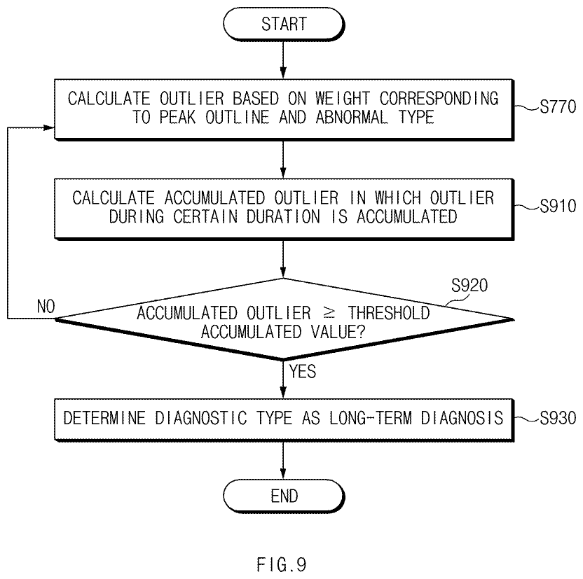

Referring to FIG. 9, in S910, an accumulated outlier in which the outlier during a certain duration is accumulated may be calculated. For example, the processor 100 may calculate the accumulated outlier where outliers from a certain duration are accumulated. Herein, the certain duration may refer to a duration when charging and discharging are repeated n times.

In S920, it may be determined whether the accumulated outlier is greater than or equal to a threshold accumulated value.

If it is determined that the accumulated outlier is greater than or equal to the threshold accumulated value, in S930, the diagnostic type may be determined as a long-term diagnosis. For example, if an accumulated outlier in which the outlier is accumulated while charging and discharging are repeated n times is greater than or equal to the threshold accumulated value, the processor 100 may determine the diagnostic type of the battery cell as the long-term diagnosis.

On the other hand, if it is determined that the accumulated outlier is less than the threshold accumulated value, the processor 100 may return to S770 and may determine the diagnostic type except for the long-term diagnosis based on the outlier.

As described above, the state diagnostic method of the state diagnostic apparatus 10 for the battery according to the present disclosure may determine the type of abnormal state in the battery and may quantify the abnormal state, thereby improving the accuracy and reliability of diagnosing the state of the battery. Furthermore, the state diagnostic method of the state diagnostic apparatus 10 for the battery may easily determine the type of the abnormal state of the battery, thus providing a response method according to the type.

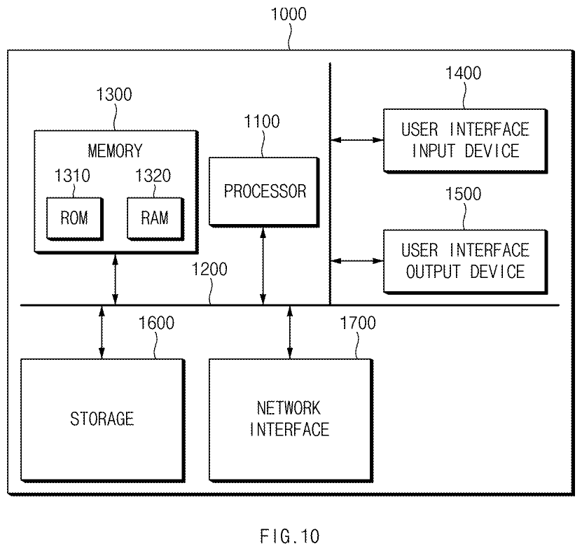

FIG. 10 is a block diagram illustrating a computing system 1000 according to an embodiment of the present disclosure.

Referring to FIG. 10, the computing system 1000 may include at least one processor 1100, a memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Accordingly, the operations of the method or algorithm described in connection with the embodiments disclosed in the specification may be directly implemented with a hardware module, a software module, or a combination of the hardware module and the software module, which is executed by the processor 1100. The software module may reside on a storage medium (i.e., the memory 1300 and/or the storage 1600) such as a RAM, a flash memory, a ROM, an EPROM, an EEPROM, a register, a hard disc, a removable disk, and a CD-ROM.

The exemplary storage medium may be coupled to the processor 1100. The processor 1100 may read out information from the storage medium and may write information into the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The user interface input device 1400 may include an input device that receives a user input.

For example, the input device may be provided as a tact switch, a joystick, a push switch, a slide switch, a toggle switch, a micro switch, or a touch screen. Furthermore, the input device may include a microphone for receiving voice input from the user.

The user interface output device 1500 may include a display for displaying various pieces of information and a speaker for outputting various sounds. Herein, the display may provide a user interface for allowing a user and the computing system 1000 to interact with each other. For example, the display may include a liquid crystal display (LCD) panel and/or a light emitting diode (LED).

The network interface 1700 may include a long range communication module and/or a short range communication module, which transmit(s) and receive(s) data with an external device (e.g., a server or a user terminal). For example, the network interface 1700 may refer to a communication module capable of performing wireless Internet communication, such as a wireless LAN (WLAN), wireless broadband (Wibro), wireless-fidelity (Wi-Fi), world interoperability for microwave access (WiMAX), or high speed downlink packet access (HSDPA).

The present technology may determine a type of abnormal state of the battery and may quantify the abnormal state, thus improving the accuracy and reliability of diagnosing the state of the battery.

Furthermore, the present technology may easily determine the type of an abnormal state of the battery, thus providing a response method according to the type.

In addition, various effects ascertained directly or indirectly through the present disclosure may be provided.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

Therefore, embodiments of the present disclosure are not intended to limit the technical spirit of the present disclosure, but are provided only for illustrative purposes. The scope of the present disclosure should be construed on the basis of the accompanying claims, and all the technical ideas within the scope equivalent to the claims should be included in the scope of the present disclosure.

1. A state diagnostic apparatus for a battery, the state diagnostic apparatus comprising:
a transceiver module configured to receive battery data of at least one battery cell; and
a processor configured to:
calculate a differential capacity based on the battery data;
determine an abnormal type for an abnormal state of the at least one battery cell based on the differential capacity;
calculate an outlier based on the abnormal type;
determine a diagnostic type corresponding to the abnormal state based on the outlier, and
provide a result corresponding to the determined diagnostic type, the result including at least one of outputting a diagnostic trouble code to notify the user of the abnormal state, guiding replacement or after-service of the battery cell, inducing an immediate detailed diagnosis related to safety, or providing a progressive monitoring process for the abnormal state.

2. The state diagnostic apparatus of claim 1, wherein the processor is further configured to:
calculate a curve of the differential capacity as a function of a voltage based on the battery data; and
calculate an outline of at least one of a peak or a valley of the curve.

3. The state diagnostic apparatus of claim 2, wherein the processor is further configured to:
set a plurality of voltage values based on the curve; and
wherein the plurality of voltage values includes a first voltage value and a second voltage value.

4. The state diagnostic apparatus of claim 3, wherein the processor is further configured to:
calculate a first relative value of the differential capacity corresponding to the first voltage value; and
calculate a second relative value of the differential capacity corresponding to the second voltage value.

5. The state diagnostic apparatus of claim 4, wherein the processor is configured to:
determine whether the first relative value is within a first reference range;
determine whether the second relative value is within a second reference range; and
determine the abnormal type based on a determined result.

6. The state diagnostic apparatus of claim 2, wherein the processor is further configured to calculate the outlier based on a weight corresponding to the outline of the at least one of the peak or the valley and the abnormal type.

7. The state diagnostic apparatus of claim 6, wherein the processor is further configured to:
determine whether the outlier is greater than or equal to a threshold; and
determine the diagnostic type corresponding to the outlier based on the determined result.

8. The state diagnostic apparatus of claim 7, wherein the processor is further configured to determine the diagnostic type as a short-term diagnosis when the outlier is greater than or equal to the threshold.

9. The state diagnostic apparatus of claim 7, wherein the processor is further configured to:
calculate an accumulated outlier by accumulating the outlier over a predetermined duration; and
determine the diagnostic type as a long-term diagnosis when the accumulated outlier is greater than or equal to a threshold accumulated value.

10. The state diagnostic apparatus of claim 1, wherein the processor is further configured to preset the abnormal type and the diagnostic type based on characteristics of the battery cell.

11. A state diagnostic method of a state diagnostic apparatus for a battery, the state diagnostic method comprising:
receiving battery data of at least one battery cell;
calculating a differential capacity based on the battery data;
determining an abnormal type for an abnormal state of the at least one battery cell based on the differential capacity;
calculating an outlier based on the abnormal type;
determining a diagnostic type corresponding to the abnormal state based on the outlier, and
providing a result corresponding to the determined diagnostic type, the result including at least one of outputting a diagnostic trouble code to notify the user of the abnormal state, guiding replacement or after-service of the battery cell, inducing an immediate detailed diagnosis related to safety, or providing a progressive monitoring process for the abnormal state.

12. The state diagnostic method of claim 11, wherein the calculating of the differential capacity comprises:
calculating a curve for the differential capacity as a function of a voltage based on the battery data; and
calculating an outline of at least one of a peak or a valley of the curve.

13. The state diagnostic method of claim 12, wherein the calculating of the differential capacity further comprises:
setting a plurality of voltage values based on the curve, and
wherein the plurality of voltage values includes a first voltage value and a second voltage value.

14. The state diagnostic method of claim 13, wherein the calculating of the differential capacity further comprises:
calculating a first relative value of the differential capacity corresponding to the first voltage value; and
calculating a second relative value of the differential capacity corresponding to the second voltage value.

15. The state diagnostic method of claim 14, wherein the determining of the abnormal type comprises:
determining whether the first relative value is within a first reference range;
determining whether the second relative value is within a second reference range; and
determining the abnormal type based on a determined result.

16. The state diagnostic method of claim 12, wherein the calculating of the outlier comprises:
calculating the outlier based on a weight corresponding to the outline of the at least one of the peak or the valley and the abnormal type.

17. The state diagnostic method of claim 16, wherein the determining of the diagnostic type comprises:
determining whether the outlier is greater than or equal to a threshold; and
determining the diagnostic type corresponding to the outlier based on the determined result.

18. The state diagnostic method of claim 17, wherein the determining of the diagnostic type further comprises determining the diagnostic type as a short-term diagnosis when the outlier is greater than or equal to the threshold.

19. The state diagnostic method of claim 17, wherein the determining of the diagnostic type further comprises:
calculating an accumulated outlier by accumulating the outlier over a predetermined duration; and
determining the diagnostic type as a long-term diagnosis when the outlier is greater than or equal to a threshold accumulated value.

20. The state diagnostic method of claim 11, further comprising presetting the abnormal type and the diagnostic type based on characteristics of the at least one battery cell.
